(19) United States
(12) Patent Application Publication
(10) Pub. No.: US 2009/0324827 A1
(43) Pub. Date: Dec. 31, 2009

(54) CVD FILM FORMING METHOD AND CVD FILM FORMING APPARATUS

(75) Inventor: Hidenori Miyoshi, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, Tokyo (JP)

(21) Appl. No.: 12/375,882

(22) PCT Filed: Jul. 18, 2007
(86) PCT No.: PCT/JP2007/064197

§ 371 Date: Jan. 30, 2009

(30) Foreign Application Priority Data
Jul. 31, 2006 (JP) 2006-208726

(51) Int. Cl. C23C 16/06; C23C 16/46; C23C 16/52

(52) U.S. Cl. 427/255.28; 118/725; 118/696

(57) ABSTRACT

A wafer W is arranged on a susceptor 22 in a chamber 21, and a metal film is formed on a surface of the wafer W by continuously supplying the chamber 21 with a metal compound gas from a metal compound gas supply unit 51 and a reducing organic compound gas from a reducing organic compound gas supply unit 52 of a gas supply mechanism 50.

### FIELD OF THE INVENTION

The present invention relates to a CVD film forming method and a CVD film forming apparatus for forming, for example, a metal layer used in a semiconductor device by CVD.

### BACKGROUND OF THE INVENTION

In manufacturing a semiconductor device, there is employed a process for forming a metal film for a wiring pattern. As a method for forming a metal film, a physical vapor deposition (PVD) method such as sputtering is widely used. However, recently, as a further miniaturization of the wiring pattern is required, the PVD method having poor step coverage has difficulty to meet the miniaturization.

For this reason, a CVD film forming method employing an oxidation reduction reaction using a metal compound gas and a reducing agent has been given attention. However, it is necessary to sufficiently reduce the metal compound gas in order to obtain a good film quality. Accordingly, after a metal oxide film is formed by using an atomic layer deposition (ALD) method for alternately supplying a metal material and an oxidizing agent, the metal oxide film is reduced by an organic compound having reducibility (see, e.g., U.S. Pat. No. 6,482,740).

However, in the method disclosed in U.S. Pat. No. 6,482,740, a metal oxide film is formed by an ALD method and a process for reducing the metal oxide film is necessary, resulting in a very complicated process.

### SUMMARY OF THE INVENTION

It is an object of the present invention to provide a CVD film forming method and a CVD film forming apparatus capable of forming a metal film by employing CVD using an oxidation reduction reaction with sufficient reducibility without undergoing a complicated process.

It is an object of the present invention to provide a computer-readable storage medium storing a program for executing the CVD film forming method.

In accordance with a first aspect of the present invention, there is provided a CVD film forming method comprising: placing a substrate to be processed in a processing chamber; and forming a metal film on a surface of the substrate by continuously supplying a gas of a metal compound and a gas of a reducing organic compound into the processing chamber.

In the first aspect of the present invention, the metal film may include at least one of Cu, Pd, Ti, W, Ta, Ru, Pt, Ir, Rh and Mn, and the metal compound contains at least one thereof.

Further, the reducing organic compound may contain at least one selected from the group consisting of alcohol, aldehyde, carboxylic acid, carboxylic acid anhydride, ester, organic acid ammonium salt, organic acid amine salt, organic acid amide, organic acid hydrazide, organic acid metal complex, and organic acid metal salt.

Further, only the reducing organic compound gas may be initially supplied into the processing chamber and, then, the metal compound gas and the reducing organic compound gas are supplied into the processing chamber. Further, a material of the metal compound gas and a material of the reducing organic compound gas may be stored in a mixed state in a single container, and the metal compound gas and the reducing organic compound gas may be supplied into the processing chamber from the container.

In accordance with a second aspect of the present invention, there is provided a CVD film forming apparatus comprising: a processing chamber for accommodating a substrate to be processed; a mounting table for mounting the substrate thereon in the processing chamber; a gas supply unit for supplying a metal compound gas and a reducing organic compound gas into the processing chamber; a gas exhaust unit for evacuating the processing chamber; and a heating unit for heating the substrate on the mounting table, wherein the metal compound gas and the reducing organic compound gas are supplied into the processing chamber to form a metal film on a surface of the substrate on the mounting table by a reaction of the gases.

In the second aspect of the present invention, the gas supply unit may include separate containers for storing a material of the metal compound gas and a material of the reducing organic compound gas, respectively. Further, the gas supply unit may include a container for storing a material of the metal compound gas and a material of the reducing organic compound gas in a mixed state, and the metal compound gas and the reducing organic compound gas are supplied into the processing chamber from the container.

In accordance with a third aspect of the present invention, there is provided a CVD film forming apparatus comprising: at least two film forming units, each unit including a processing chamber for accommodating a substrate to be processed, the processing chamber being maintained in a vacuum state, a mounting table for mounting the substrate thereon in the processing chamber, a gas supply unit for supplying a metal compound gas and a reducing organic compound gas into the processing chamber, a gas exhaust unit for evacuating the processing chamber, and a heating unit for heating the substrate on the mounting table; and a substrate transfer unit for transferring the substrate between the film forming units without breaking the vacuum state, wherein a first metal film is formed on a surface of the substrate by a reaction of the metal compound gas and the reducing organic compound gas in any one of the film forming units and, after the substrate is transferred to another one of the film forming units by using the substrate transfer unit, a second metal film is formed on the first metal film continuously by a reaction of the metal compound gas and the reducing organic compound gas without breaking the vacuum state.

In accordance with a fourth aspect of the present invention, there is provided a storage medium which is operated on a computer and stores a program for controlling a CVD film forming apparatus, wherein the program controls the CVD film forming apparatus to perform a CVD film forming method including: placing a substrate to be processed in a processing chamber; and forming a metal film on a surface of the substrate by continuously supplying a metal compound gas and a reducing organic compound gas into the processing chamber.

In accordance with the present invention, the metal compound gas and the reducing organic compound gas are continuously supplied to the processing chamber. Accordingly, an oxidation reduction reaction occurs between the gases and the metal compound gas is directly reduced by the reducing organic compound gas having strong reducing power. Thus, it is possible to form a metal film with sufficient reducibility through CVD without undergoing a complicated process. Further, it is possible to form a metal film at a relatively low temperature and at a high speed by high reducibility of the reducing organic compound.

### BRIEF DESCRIPTION OF THE DRAWINGS

FIG. 1 schematically shows a cross sectional view of a film forming apparatus for performing a CVD film forming method in accordance with an embodiment of the present invention.

FIG. 2 schematically shows an example of a metal compound gas supply unit in the film forming apparatus shown in FIG. 1.

FIG. 3 schematically shows another example of the metal compound gas supply unit in the film forming apparatus shown in FIG. 1.

FIG. 4 schematically shows still another example of the metal compound gas supply unit in the film forming apparatus shown in FIG. 1.

FIG. 5 schematically shows still another example of the metal compound gas supply unit in the film forming apparatus shown in FIG. 1.

FIG. 6A is a cross sectional view of a step in an application example of the method of the present invention.

FIG. 6B is a cross sectional view of a step in an application example of the method of the present invention.

FIG. 6C is a cross sectional view of a step in an application example of the method of the present invention.

FIG. 6D is a cross sectional view of a step in an application example of the method of the present invention.

FIG. 7 schematically shows a film forming system capable of continuously forming a barrier film and a Cu film without breaking the vacuum state, the film forming system including the film forming apparatus for performing the film forming method in accordance with the present invention.

### DETAILED DESCRIPTION OF THE EMBODIMENTS

Hereinafter, embodiments of the present invention will be described in detail with reference to the accompanying drawings which form a part hereof.

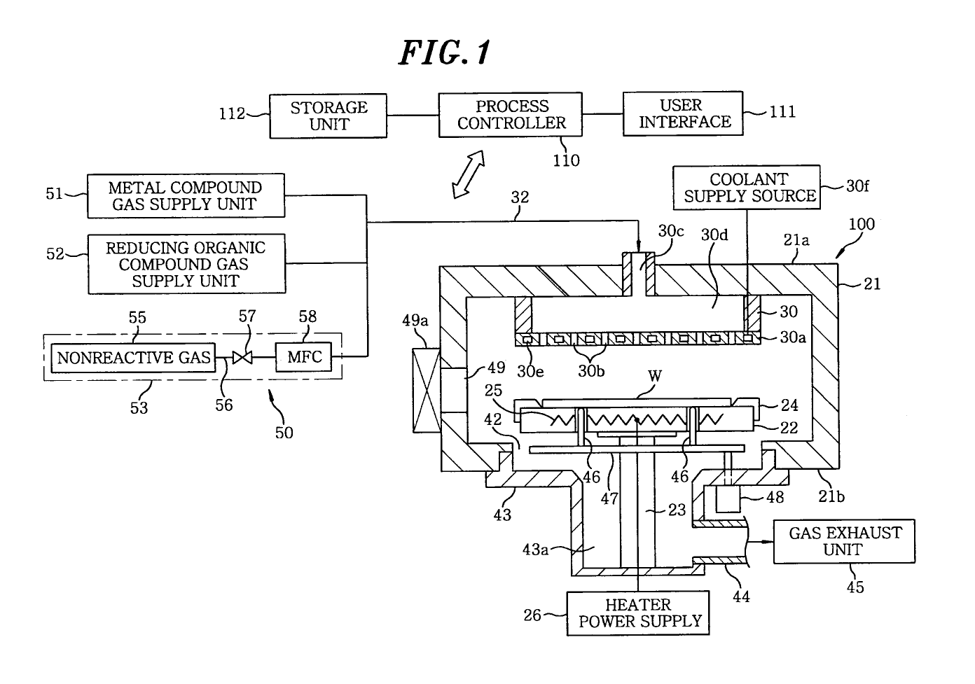

FIG. 1 schematically shows a cross sectional view of a film forming apparatus for performing a CVD film forming method in accordance with an embodiment of the present invention.

The film forming apparatus 100 includes an airtightly sealed and approximately cylindrical chamber 21. A circular opening 42 is formed at a central portion of a lower wall 21b of the chamber 21. A gas exhaust chamber 43 communicating with the opening 42 is provided at the lower wall 21b to be protruded downward. A susceptor 22 is disposed in the chamber 21 to horizontally support a wafer W serving as a semiconductor substrate. The susceptor 22 is supported by a cylindrical supporting member 23 extending upward from a central bottom portion of the gas exhaust chamber 43. A guide ring 24 is provided at an outer peripheral portion of the susceptor 22 to guide the wafer W. Further, a resistance heater 25 is embedded in the susceptor 22. The heater 25 is supplied with power from a heater power supply 26 to heat the susceptor 22, thereby heating the wafer W. Further, the heater power supply 26 is connected to a controller (not shown) such that an output of the heater 25 is controlled based on a signal of a temperature sensor (not shown). Further, a heater (not shown) is buried in the wall of the chamber 21 to heat the wall of the chamber 21.

Further, the susceptor 22 is provided with, for example, three wafer supporting pins (only two pins are shown) 46 for moving the wafer W up and down while being protruded from a surface of the susceptor 22 and retracted into the susceptor 22. The wafer supporting pins 46 are fixed to a support plate 47. The wafer supporting pins 46 moves up and down through the support plate 47 by using a drive mechanism 48 such as an air cylinder.

A shower head 30 is provided at a ceiling wall 21a of the chamber 21. A shower plate 30a is disposed at a lower portion of the shower head 30 and has a number of gas discharge holes 30b for discharging a gas toward the susceptor 22. A gas inlet port 30c is provided at an upper wall of the shower head 30 to introduce a gas into the shower head 30. The gas inlet port 30c is connected to a gas supply line 32. Further, a diffusion area 30d is formed in the shower head 30. The shower plate 30a is provided with, for example, concentric coolant channels 30e to prevent decomposition of a metal compound gas or the like in the shower head 30. A coolant such as cooling water is supplied to the coolant channels 30e from a coolant supply source 30f for appropriate temperature control.

A gas supply mechanism 50 is connected to the other end of the gas supply line 32. The gas supply mechanism 50 includes a metal compound gas supply unit 51 for supplying a metal compound gas, a reducing organic compound gas supply unit 52 for supplying a reducing organic compound gas, and a nonreactive gas supply unit 53 for supplying a nonreactive gas serving as, e.g., a dilution gas for pressure control to the chamber 21. Further, the metal compound gas supply unit 51 supplies a metal compound gas by using various methods to be described later depending on types of metal compound materials. Further, the reducing organic compound gas supply unit 52 supplies a reducing organic compound gas by using various methods to be described later depending on types of reducing organic compound materials. The nonreactive gas supply unit 53 includes a nonreactive gas supply source 55 for supplying a nonreactive gas, a nonreactive gas supply line 56 extending from the nonreactive gas supply source 55 to be connected to the gas supply line 32, and a valve 57 and a mass flow controller (MFC) 58 provided in the nonreactive gas supply line 56. As examples of the nonreactive gas, there are a N₂ gas, an Ar gas and a He gas. The nonreactive gas supply line may be connected to lines of the metal compound gas supply unit 51 and the reducing organic compound gas supply unit 52 such that a nonreactive gas can be used as a purge gas. Further, the nonreactive gas supply source may be omitted.

The metal compound gas and the reducing organic compound gas are supplied into the chamber 21 from the gas supply mechanism 50. Then, an oxidation-reduction reaction occurs on the wafer W heated to an appropriate temperature, and the metal compound gas is reduced to thereby form a metal film on the wafer W.

A gas exhaust pipe 44 is connected to a side of the gas exhaust chamber 43 to communicate therewith. The gas exhaust pipe 44 is connected to a gas exhaust unit 45 including a high speed vacuum pump. As the gas exhaust unit 45 is operated, the gas in the chamber 21 is uniformly discharged into a space 43a of the gas exhaust chamber 43, and an inner pressure of the chamber 21 can be reduced to a specific vacuum level at a high speed through the gas exhaust pipe 44.

A loading/unloading port 49 and a gate valve 49a for opening and closing the loading/unloading port 49 are provided at a sidewall of the chamber 21. The wafer W is transferred between the chamber 21 and a transfer chamber (not shown) adjacent to the film forming apparatus 100 through the loading/unloading port 49.

Each component of the film forming apparatus 100 is connected to and controlled by a process controller 110. A user interface 111, including a keyboard for inputting commands or a display for displaying an operation status of the film forming apparatus 100, is connected to the process controller 110 to allow a process manager to manage the film forming apparatus 100.

Further, the process controller 110 is connected to a storage unit 112 which stores recipes including control programs for implementing various processes in the film forming apparatus 100 under control of the process controller 110, and a program for performing a process in each component of the film forming apparatus 100 in accordance with process conditions. Further, the recipes may be stored in a hard disk or a semiconductor memory, or may be stored in a portable storage medium such as a CD-ROM and DVD to be set at a specific position of the storage unit 112. Further, the recipes may be appropriately transmitted via, for example, a dedicated line from another apparatus.

If necessary, a certain recipe is retrieved from the storage unit 112 in accordance with an instruction inputted through the user interface 51 to be transmitted to the process controller 110, so that a desired process is performed in the film forming apparatus 100 under control of the process controller 110.

Next, the metal compound gas supply unit 51 is explained in detail.

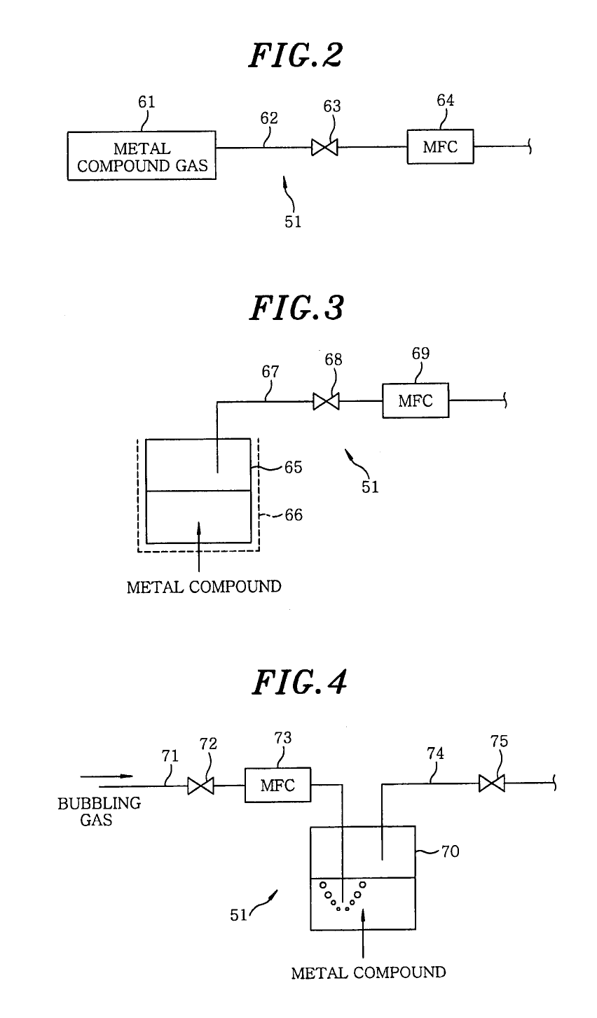

First, when a metal compound material is in a gas phase at a room temperature, as shown in FIG. 2, the metal compound gas supply unit 51 may include a metal compound gas supply source 61 for supplying a metal compound gas, a metal compound gas supply line 62 extending from the metal compound gas supply source 61 to be connected to the gas supply line 32, and a valve 63 and a mass flow controller (MFC) 64 provided in the metal compound gas supply line 62.

Further, when a metal compound material is in a liquid or solid phase at a room temperature, as shown in FIG. 3, the metal compound gas supply unit 51 may include a source container 65 for containing a metal compound material, a heater 66 for heating the source container 65 to vaporize or sublimate the metal compound material, and a metal compound gas supply line 67 for supplying vapor of the metal compound material, the metal compound gas supply line 67 extending from the source container 65 to be connected to the gas supply line 32. The metal compound gas supply line 67 is provided with a valve 68 and a mass flow controller (MFC) 69.

As another example, when a metal compound material is in a liquid or solid phase at a room temperature, as shown in FIG. 4, the metal compound gas supply unit 51 may include a source container 70 for containing a metal compound material, a bubbling gas line 71 for injecting a bubbling gas into the metal compound material in the source container 70, and a metal compound gas line 74 for supplying vapor of the metal compound material produced by bubbling, the metal compound gas line 74 extending from the source container 70 to be connected to the gas supply line 32. The bubbling gas line 71 is provided with a valve 72 and a mass flow controller (MFC) 73. The metal compound gas line 74 is provided with a valve 75.

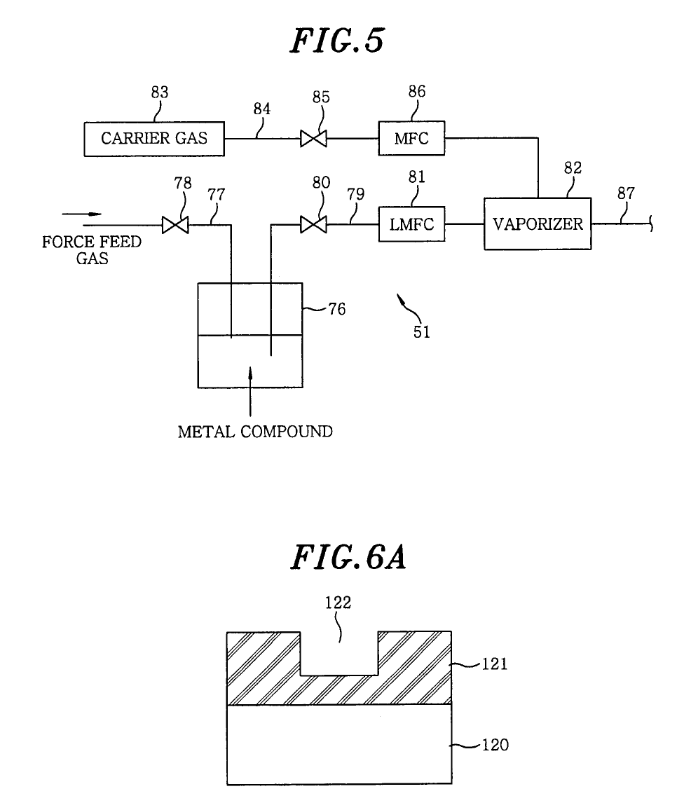

As still another example, when a metal compound material is in a liquid phase at a room temperature, as shown in FIG. 5, the metal compound gas supply unit 51 may include a source container 76 for containing a liquid metal compound material, a pressure feed gas line 77 for supplying a pressure feed gas into the source container 76, a metal compound material supply line 79 extending from the source container 76 to supply the liquid metal compound material therethrough, a vaporizer 82 connected to the metal compound material supply line 79, a carrier gas supply source 83 and a carrier gas supply line 84 for supplying a carrier gas to the vaporizer 82, and a metal compound gas supply line 87 for connecting the vaporizer 82 to the gas supply line 32 and transmitting a metal compound gas vaporized in the vaporizer 82 to the gas supply line 32. The pressure feed gas line 77 is provided with a valve 78, and the metal compound material supply line 79 is provided with a valve 80 and a liquid mass flow controller (LMFC) 81. The carrier gas supply line 84 is provided with a valve 85 and a mass flow controller (MFC) 86.

Further, the reducing organic compound gas supply unit 52 for supplying a reducing organic compound gas may be configured in the same way as the metal compound gas supply units 51 shown in FIGS. 2 to 5.

Hereinafter, a film forming method using the film forming apparatus 100 having the above configuration in accordance with the embodiment of the present invention will be described.

First, while a gate valve 49a is opened, the wafer W is loaded into the chamber 21 through the loading/unloading port 49 to be mounted on the susceptor 22. The susceptor 22 is heated in advance to a predetermined temperature to thereby heat the wafer W. Further, the chamber 21 is evacuated by using a vacuum pump of the gas exhaust unit 45 such that an inner pressure of the chamber 21 is adjusted to a specific value.

In this state, a certain metal compound gas and a certain reducing organic compound gas are supplied to the wafer W in the chamber 21 through the shower head 30 from the metal compound gas supply unit 51 and the reducing organic compound gas supply unit 52 of the gas supply mechanism 50, respectively. An oxidation reduction reaction occurs between the metal compound gas and the reducing organic compound gas on the wafer W to reduce the metal compound gas, thereby forming a metal film on the wafer W.

Although a metal compound gas and a reducing organic compound gas are supplied from separate containers in the above embodiment, when the gases have low reactivity at a storage temperature, a material of the metal compound gas and a material of the reducing organic compound gas may be stored in a mixed state in a single container. In this case, a ratio of the materials of the metal compound gas and the reducing organic compound gas stored in the storage container may be adjusted such that the gases are supplied at a specific mixing ratio. Further, it is preferable to employ the gas supply unit 51 using a vaporizer shown in FIG. 5 or the gas supply unit 51 using bubbling shown in FIG. 4 in order to reduce any influence due to a difference in vapor pressures between the gases on their mixing ratio.

When the material of the metal compound gas and the material of the reducing organic compound gas are solid, that is, when the materials cannot be uniformly mixed in the storage container, the materials can be stored by being dissolved in an appropriate solvent such as hexane, toluene, xylene and butyl acetate.

As described above, the reducing organic compound gas has a strong reducing power to directly reduce the metal compound gas, thereby forming a metal film. Conventionally, a metal oxide film is formed by using an ALD method or the like and, then, the oxide film is reduced by the reducing organic compound. However, it is verified that a metal film can be obtained by simultaneously supplying the reducing organic compound gas and the metal compound gas. Accordingly, it is possible to form a metal film with sufficient reducibility by employing CVD without a conventional complicated process.

Further, since the metal compound serving as a material of the metal film is reduced by using the reducing organic compound having high reducibility, it is possible to form a metal film at a relatively low temperature and at a high speed.

The metals and metal compounds applicable for the present invention are as follows.

Metal films to be deposited in accordance with the embodiment of the present invention may include a Cu film, a Pd film, a Ti film, a W film, a Ta film, a Ru film, a Pt film, an Ir film, a Rh film, a Mn film and an alloy film thereof. The Cu film, the W film, the Pt film, the Ir film and the Rh film may be used as, for example, a wiring layer. The Pd film, the Ti film, the Ta film, the Ru film and the Mn film may be used as, for example, a barrier layer.

When a Cu film is formed as a metal film, the metal compound materials may include Cu(hexafluoroacetylacetonate) (Cu(hfac)₂), Cu(acetylacetonate) (Cu(acac)₂), Cu(dipivaloylmethanate) (Cu(dpm)₂), Cu(diisobutyrylmethanate) (Cu(dibm)₂), Cu(isobutyrylpivaloylmethanate) (Cu(ibpm)₂), bis(6-ethyl-2,2-dimethyl-3,5-decanedionato) copper (Cu(edmdd)₂), Cu(hexafluoroacetylacetonate) trimethylvinylsilane (Cu(hfac)TMVS), and Cu(hexafluoroacetylacetonate) 1,5-cyclooctadiene (Cu(hfac)COD).

When a Pd film is formed as a metal film, the metal compound materials may include palladium hexafluoroacetylacetonate (Pd(hfac)₂), (cyclopentadienyl)palladium(allyl)((C₅H₅) Pd(allyl)), and palladium(allyl)(Pd(allyl₂)).

When a Ti film is formed as a metal film, the metal compound materials may include titanium tetrachloride (TiCl₄), titanium tetrafluoride (TiF₄), titanium tetrabromide (TiBr₄), titanium tetraiodide (TiI₄) tetrakis(ethylmethylamino)titanium (Ti[N(C₂H₅CH₃)₂]₄(TEMAT)), tetrakis(dimethylamino)titanium (Ti[N(CH₃)₂]₄(TDMAT)), and tetrakis (diethylamino) titanium (Ti[N(C₂H₅)₂]₄(TDEAT)).

When a W film is formed as a metal film, the metal compound materials may include tungsten hexafluoride (WF₆) and tungsten carbonyl (W(CO)₆).

When a Ta film is formed as a metal film, the metal compound materials may include tantalum pentachloride (TaCl₅), tantalum pentafluoride (TaF₅), tantalum pentabromide (TaBr₅), tantalum pentaiodide (TaI₅), tert-butylimido-tris(diethylamido)tantalum (Ta(NC(CH₃)₃)(N(C₂H₅)₂)₃(TBTDET)), tert-amylimido-tris(dimethylamide)tantalum (Ta(NC(CH₃)₂C₂H₅) (N(CH₃)₂)₃).

When a Ru film is formed as a metal film, the metal compound materials may include bis(cyclopentadienyl)ruthenium, tris(2,2,6,6-tetramethyl-3,5-heptanedionato)ruthenium, tris(N,N′-diisopropylacetamidinate)ruthenium(III), bis(N,N′-diisopropylacetamidinate)ruthenium(II)dicarbonyl, bis(ethylcyclopentadienyl)ruthenium, bis(pentamethylcyclopentadienyl)ruthenium, bis(2,2,6,6, -tetramethyl-3,5-heptanedionato)(1,5-cyclooctadiene)ruthenium(II), and ruthenium(III) acetylacetonate.

When a Pt(platinum) film is formed as a metal film, the metal compound materials may include (trimethyl)methylcyclopentadienylplatinum(IV), platinum(II)acetylacetonate, bis(2,2,6,6-tetramethyl-3,5-heptanedionato)platinum(II), and platinum (II)hexafluoroacetylacetonate.

When an Ir film is formed as a metal film, the metal compound materials may include 1,5-cyclooctadiene(acetylacetonate)iridium(I) dicarbonyl(acetylacetonate)iridium(I), and iridium (III) acetylacetonate.

When a Rh film is formed as a metal film, the metal compound materials may include (acetylacetonate)bis(cyclooctene)rhodium(1I (acetylacetonate)bis(ethylene)rhodium(I), acetylacetonate(1,5-cyclooctadiene)rhodium(I) and rhodium (III) acetylacetonate.

When a Mn film formed as a metal film, the metal compound materials may include bis(cyclopentadienyl)manganese (Mn(C₅H₅)₂) bis(methylcyclopentadienyl)manganese (Mn(CH₃C₅H₄)₂) bis(ethylcyclopentadienyl)manganese (Mn(C₂H₅C₅H₄)₂) bis(isopropylcyclopentadienyl)manganese (Mn(C₃H₇C₅H₄)₂) bis(t-butylcyclopentadienyl)manganese (Mn(C₄H₉C₅H₄)₂), bis(acetylacetonate)manganese (Mn(C₅H₇O₂)₂) bis(pentamethylcyclopentadienyl)manganese(II) (Mn(C₅(CH₃)₅)₂) bis(tetramethylcyclopentadienyl)manganese(II) (Mn(C₅(CH₃)₄H)₂), (DMPD)(ethylcyclopentadienyl)manganese (Mn(C₇H₁₁C₂H₅C₅H₄)), tris(DPM)manganese (Mn(C₁₁,H₁₉O₂)₃), manganese(0)carbonyl (Mn₂(CO)₁₀) methylmanganese pentacarbonyl (CH₃Mn(CO)₅), cyclopentadienyl manganese(I)tricarbonyl ((C₅H₅)Mn(CO)₃), methylcyclopentadienyl manganese (I) tricarbonyl ((CH₃C₅H₄)Mn(CO)₃), ethylcyclopentadienyl manganese(I)tricarbonyl ((C₂H₅C₅H₄)Mn(CO)₃), acetylcyclopentadienyl manganese(I) tricarbonyl ((CH₃COC₅H₄) Mn (CO)₃), hydroxylisopropylcyclopentadienyl manganese(I)tricarbonyl ((CH₃)₂C(OH)C₅H₄) Mn(CO)₃).

Further, reducing organic compounds for reducing a metal compound serving as a material of the metal film may include alcohol having a hydroxyl group (—OH), aldehyde having an aldehyde group (—CHO), carboxylic acid having a carboxyl group (—COOH), carboxylic acid anhydride, ester, organic acid ammonium salt, organic acid amine salt, organic acid amide, organic acid hydrazide, organic acid metal complex, and organic acid metal salt. Further, at least one thereof may be used as a reducing organic compound.

The alcohol includes primary alcohol, particularly, primary alcohol having the following formula (1):

R¹—OH (1)

(R¹ is a straight or branched C₁˜C₂₀ alkyl or alkenyl group, preferably, methyl, ethyl, propyl, butyl, pentyl or hexyl), for example, methanol (CH₃OH), ethanol (CH₃CH₂OH), propanol (CH₃CH₂CH₂OH), butanol (CH₃CH₂CH₂CH₂OH), 2-methyl-propanol ((CH₃)₂CHCH₂OH), and 2-methyl butanol (CH₃CH₂CH(CH₃)CH₂OH);

secondary alcohol, particularly, secondary alcohol having the following formula (2):

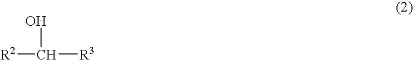

(R², R³ is a straight or branched C₁˜C₂₀ alkyl or alkenyl group, preferably, methyl, ethyl, propyl, butyl, pentyl or hexyl), for example, 2-propanol ((CH₃)₂CHOH), and 2-butanol (CH₃CH(OH)CH₂CH₃);

polyhydroxy alcohol such as diol or triol, for example, ethylene glycol (HOC₂CH₂OH), glycerol (HOCH₂CH(OH)CH₂OH);

cyclic alcohol having 1˜10, typically, 5˜6 carbon atoms in a portion of a ring;

benzyl alcohol (C₆H₅CH₂OH), aromatic alcohol of o-, p- or m-cresol, resorcinol, etc.;

halogenated alcohol, particularly, halogenated alcohol having the following formula (3):

CHₙX₃₋ₙ—R⁴—OH (3)

(X is F, Cl, Br or I, preferably, F or Cl, n is an integral number of 0˜2, and R⁴ is a straight or branched C₁˜C₂₀ alkyl or alkenyl group, preferably, methylene, ethylene, trimethylene, tetramethylene, pentamethylene or hexamethylene), for example, 2,2,2-trifluoroethanol (CF₃CH₂OH);

other alcohol derivatives, for example, methylethanolamine (CH₃NHCH₂CH₂OH).

The aldehyde includes aldehyde having the following formula (4):

R⁵—CHO (4)

(R⁵ is hydrogen, or a straight or branched C₁˜C₂₀ alkyl or alkenyl group, preferably, methyl, ethyl, propyl, butyl, pentyl or hexyl), for example, formaldehyde (HCHO), acetaldehyde (CH₃CHO) and butylaldehyde (CH₃CH₂CH₂CHO); alkanediol compounds having the following formula (5):

OHC—R⁶—CHO (5)

(R⁶ is a straight or branched C₁˜C₂₀ saturated or unsaturated hydrocarbon, but both aldehyde groups may be coupled to each other without R⁶);

halogenated aldehyde;

other aldehyde derivatives and the like.

The carboxylic acid includes carboxylic acid having the following formula (6):

R⁷—COOH (6)

(R⁷ is hydrogen, or a straight or branched C₁˜C₂₀ alkyl or alkenyl group, preferably, methyl, ethyl, propyl, butyl, pentyl or hexyl), for example, formic acid, and acetic acid (CH₃COOH);

polycarboxylic acid;

carboxylic acid halide;

other carboxylic acid derivatives and the like.

The carboxylic acid anhydride may be represented by R⁸—CO—O—CO—R⁹ (R⁸, R⁹ is a hydrogen atom, a hydrocarbon group, or a halogen-substituted hydrocarbon group in which at least one hydrogen atom forming a hydrocarbon group is substituted with halogen atom(s)). The hydrocarbon groups may include an alkyl group, an alkenyl group, an alkynyl group and an allyl group. As examples of halogen atoms, there are fluorine, chlorine, bromine and iodine. As examples of carboxylic acid anhydride, there are formic acid anhydride, propionic acid anhydride, acetic formic acid anhydride, butyric acid anhydride, and valeric acid anhydride in addition to acetic acid anhydride. However, since the formic acid anhydride and acetic formic acid anhydride are relatively unstable materials, it is preferable to use materials other than formic acid anhydride and acetic formic acid anhydride.

The ester may be represented by R¹⁰—COO—R¹¹ (R¹⁰ is a hydrogen atom, a hydrocarbon group, or a halogen-substituted hydrocarbon group in which at least one hydrogen atom forming a hydrocarbon group is substituted with halogen atom(s), and R¹¹ is a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of ester, there are methyl formate, ethyl formate, propyl formate, butyl formate, benzyl formate, methyl acetate, ethyl acetate, propyl acetate, butyl acetate, pentyl acetate, hexyl acetate, octyl acetate, phenyl acetate, benzyl acetate, allyl acetate, propenyl acetate, methyl propionate, ethyl propionate, butyl propionate, pentyl propionate, benzyl propionate, methyl butyrate, ethyl butyrate, pentyl butyrate, butyl butyrate, methyl valerate, and ethyl valerate.

The organic acid ammonium salt and the organic acid amine salt may be represented by R¹²—COO—NR¹³R¹⁴R¹⁵R¹⁶ (R¹², R¹³, R¹⁴, R¹⁵, R¹⁶ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of organic acid ammonium salt and organic acid amine salt, there are organic acid ammonium (R¹²COONH₄), primary amine salt such as organic acid methylamine salt, organic acid ethylamine salt and organic acid t-butylamine salt, secondary amine salt such as organic acid dimethylamine salt, organic acid ethylmethylamine salt and organic acid diethylamine salt, tertiary amine salt such as organic acid trimethylamine salt, organic acid diethylmethylamine salt, organic acid ethyldimethylamine salt and organic acid trimethylamine salt, and quaternary ammonium salt such as organic acid tetramethyl ammonium and organic acid triethylmethyl ammonium.

The organic acid amide may be represented by R¹⁷—CO—NH₂ (R¹⁷ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As an example of organic acid amide, there is carboxylic acid amide (R¹⁷CONH₂).

The organic acid hydrazide may be represented by R¹⁸—CO—NH—NH₂ (R¹⁸ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of organic acid forming the organic acid hydrazide, there are formic acid, acetic acid, propionic acid, butyric acid, acetic formic acid and valeric acid.

The metal complex or metal salt may be represented by Mₐ(R¹⁹COO)_{b} (M is a metal atom, a and b are natural numbers, and R¹⁹ is a hydrogen atom, a hydrocarbon group, or a halogen-substituted hydrocarbon group in which at least one hydrogen atom forming a hydrocarbon group is substituted with halogen atom(s)). Examples of the hydrocarbon group and halogen atoms are the same as the above-mentioned examples. As examples of the metal complex of organic acid or metal salt of organic acid, there are Ti, Ru, Cu, Si, Co and Al. As examples of the organic acid forming the metal complex of organic acid or metal salt of organic acid, there are formic acid, acetic acid, propionic acid, butyric acid, acetic formic acid and valeric acid. As examples of the metal complex of organic acid or metal salt of organic acid, there are titanium formate, ruthenium formate, copper formate, silicon formate, cobalt formate, and aluminum formate when the organic acid is formic acid; titanium acetate, ruthenium acetate, copper acetate, silicon acetate, cobalt acetate and aluminum acetate when the organic acid is acetic acid; and titanium propionate, ruthenium propionate, copper propionate, silicon propionate, cobalt propionate and aluminum propionate when the organic acid is propionic acid.

When a metal film is formed, if a base has been oxidized, there is a worrisome possibility that the metal film may be formed with insufficient characteristics. In order to prevent such a defect, preferably, the reducing organic compound gas is supplied in advance to the chamber 21. The reducing organic compound causes a reduction on the surface of the wafer W before film formation. Then, both the metal compound gas and the reducing organic compound gas are supplied to thereby form a metal film having a good quality in a state where the base is not oxidized. This effect can be efficiently obtained when the metal film is formed on the base having an oxide film capable of being relatively easily reduced. For example, when a metal film for wiring is formed on a Ru barrier film serving as a base, although a natural oxide film is formed on the surface of the Ru film, the oxide film can be reduced by using the above-described method, thereby forming a film having a good quality.

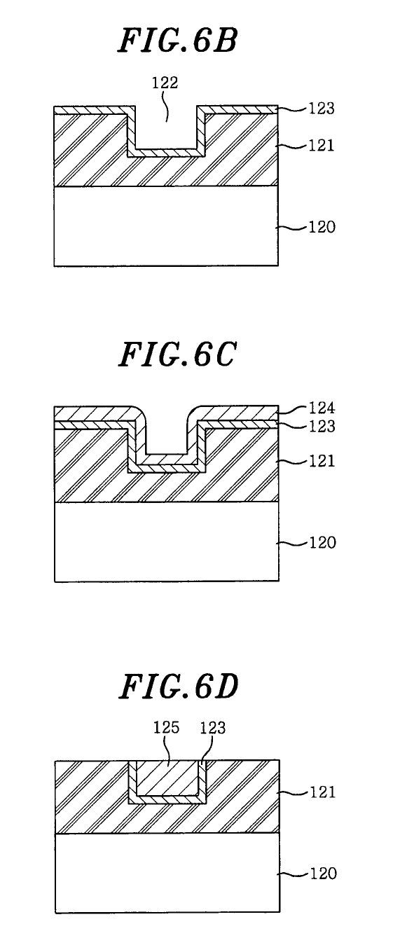

Next, an application example of the method of the present invention is explained with reference to FIGS. 6A to 6D. FIGS. 6A to 6D illustrate a process for forming a Cu line by using a damascene method. First, an interlayer insulating film 121 is formed on a Si substrate 120, and a groove 122 is formed in the interlayer insulating film 121 (FIG. 6A). Then, for example, a Ti film or Ru film is formed as a barrier film 123 by CVD (FIG. 6B) and a Cu film 124 of wiring metal is formed thereon by CVD (FIG. 6C). Then, an unfilled portion of the groove 122 is filled with Cu plating. The barrier film 123 and the Cu film 124 outside the groove 122 are removed by a chemical mechanical polishing (CMP) process to form a Cu line 125 (FIG. 6D). Further, after the Cu film 124 is formed, an unfilled portion of the groove 122 may be filled by further forming a Cu film by CVD. The barrier film 123 and the Cu film 124 may be formed by introducing the metal compound gas and the reducing organic compound gas into the chamber 21 in accordance with the embodiment of the present invention.

In this case, before the Cu film 124 is formed, it is preferable to introduce the reducing organic compound in advance in order to remove the natural oxide film of the base. However, in order to surely exclude any influence due to oxidation on the Cu film 124, it is more preferable to form the Cu film 124 without passing through an air atmosphere after the barrier film 123 is formed.

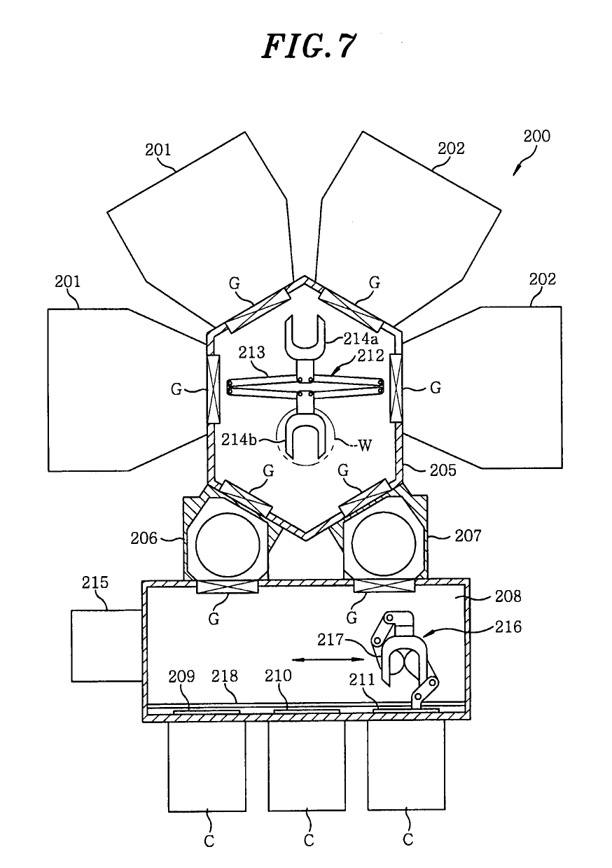

An apparatus for continuously forming two films of the barrier film and the Cu film without passing through an air atmosphere is shown in FIG. 7. FIG. 7 schematically shows a cluster tool type film forming system capable of continuously forming the barrier film and the Cu film without breaking the vacuum state.

The film forming system 200 includes two barrier film forming apparatuses 201 for forming a barrier film and two Cu film forming apparatuses 202 for forming a Cu film, the apparatuses being provided corresponding to four sides of a hexagonal wafer transfer chamber 205, respectively. The barrier film forming apparatuses 201 and the Cu film forming apparatuses 202 have the same configuration as the configuration of the above-described film forming apparatus 100. Further, load-lock chambers 206 and 207 are provided at the other two sides of the wafer transfer chamber 205. A wafer loading/unloading chamber 208 is connected to the load-lock chambers 206 and 207 on the opposite side to the wafer transfer chamber 205. Ports 209, 210 and 212 for attachment of three carriers C containing wafers W are provided at the wafer loading/unloading chamber 208 on the opposite side to the load-lock chambers 206 and 207.

Chambers of the barrier film forming apparatuses 201 and the Cu film forming apparatuses 202 are connected to the wafer transfer chamber 205 through gate valves G. Further, the load-lock chambers 206 and 207 are connected to the wafer transfer chamber 205 through gate valves G as well. Each chamber communicates with the wafer transfer chamber 205 by opening the corresponding gate valve G and is isolated from the wafer transfer chamber 205 by closing the gate valve G. Further, gate valves G are also provided at connection portions between the load-lock chambers 206 and 207 and the wafer loading/unloading chamber 208. The load-lock chamber 206 or 207 communicates with the wafer loading/unloading chamber 208 by opening the corresponding gate valve G and is isolated from the wafer loading/unloading chamber 208 by closing the gate valve G. The wafer transfer chamber 205 is maintained at a predetermined vacuum level. The load-lock chamber 206 or 207 can be depressurized at a predetermined vacuum level when it communicates with the wafer transfer chamber 205 and have an air atmosphere when it communicates with the wafer loading/unloading chamber 208.

A wafer transfer unit 212 is disposed in the wafer transfer chamber 205 and the wafer transfer unit 212 performs a delivery of the wafer W between the barrier film forming apparatuses 201, the Cu film forming apparatuses 202 and the load-lock chambers 206 and 207. The wafer transfer unit 212 is disposed at an appropriately central portion of the wafer transfer chamber 205. Two blades 214a and 214b for supporting the wafer W are provided at a leading end of a rotatable and extensible/contractible portion 213. The two blades 214a and 214b are attached to the rotatable and extensible/contractible portion 213 in opposite directions.

Shutters (not shown) are provided at three ports 209, 210 and 211 of the wafer loading/unloading chamber 208 for attachment of the carriers C. The carrier C containing the wafers W or empty carrier C is attached directly to the port 209, 210 or 211. When the carriers C are attached to the ports, the shutters are closed and the carriers C communicate with the wafer loading/unloading chamber 208 while preventing infiltration of outside air. Further, an alignment chamber 215 is provided at a side surface of the wafer loading/unloading chamber 208, and an alignment of the wafer W is performed in the alignment chamber 215.

A wafer transfer unit 216 is disposed in the wafer loading/unloading chamber 208 and the wafer transfer unit 216 performs loading/unloading of the wafer W to/from the carriers C and loading/unloading of the wafer W to/from the load-lock chambers 206 and 207. The wafer transfer unit 216 has a multi-joint arm structure and can move on a rail 218 along an arrangement direction of the carriers C. The wafer W is transferred while being loaded on a hand 217 provided at a leading end of the wafer transfer unit 216.

In the wafer processing system 200 having the above configuration, first, a single wafer W having the structure shown in FIG. 6A is unloaded from the carrier C by using the wafer transfer unit 216 and loaded in the load-lock chamber 206 or 207. An inner pressure of the load-lock chamber in which the wafer W is loaded is reduced and the load-lock chamber is made to communicate with the wafer transfer chamber 205. Then, the wafer W is loaded into the chamber of any one of the barrier film forming apparatuses 201 by using the wafer transfer unit 212. Then, the wafer W having a barrier film is loaded into any one of the Cu film forming apparatuses 202 by using the wafer transfer unit 212, and a Cu film is formed on the barrier film. Then, the wafer W having the Cu film formed on the barrier film is loaded into the load-lock chamber 207 or 206 maintained at a predetermined vacuum level by using the wafer transfer unit 212. Then, the gate valve G between the load-lock chamber and the wafer transfer chamber 205 is closed and the inside of the load-lock chamber is made to have an air atmosphere. The load-lock chamber is made to communicate with the wafer loading/unloading chamber 208 and the wafer W is returned to the carrier C by using the wafer transfer unit 216.

In this way, since the Cu film is formed without breaking the vacuum state after the barrier film is formed, the surface of the barrier film is not oxidized and the Cu film is not influenced by the oxide film. When the barrier film is formed on the metal film, it is necessary to remove a natural oxide film. However, in this case, the reducing organic compound is introduced before film formation to reduce and remove the oxide film. In order to surely remove the natural oxide film, preferably, an apparatus for removing the natural oxide film is provided in the film forming system 200 to remove the natural oxide film before film formation.

Further, various modifications may be made without being limited to the embodiment of the present invention. For example, although a Cu film or the like is formed as a metal film in the above-described embodiment, the present invention is not limited thereto. That is, the metal film may be any film capable of being formed by an oxidation reduction reaction between the metal compound and the reducing organic compound. Further, although a single wafer film forming apparatus is used in the above embodiment, a batch type film forming apparatus may be employed. Further, although a semiconductor wafer is used as a substrate in the above embodiment, the present invention may be applied to other substrates such as a substrate for a liquid crystal display device (LCD) without being limited thereto.

### INDUSTRIAL APPLICABILITY

The present invention is applicable for film formation of a metal film for metal wiring of a semiconductor device.

What is claimed is:

1. A CVD film forming method comprising:
placing a substrate to be processed in a processing chamber; and
forming a metal film on a surface of the substrate by continuously supplying a gas of a metal compound and a gas of a reducing organic compound into the processing chamber.

2. The CVD film forming method of claim 1, wherein the metal film includes at least one of Cu, Pd, Ti, W, Ta, Ru, Pt, Ir, Rh and Mn, and the metal compound contains at least one thereof.

3. The CVD film forming method of claim 1, wherein the reducing organic compound contains at least one selected from the group consisting of alcohol, aldehyde, carboxylic acid, carboxylic acid anhydride, ester, organic acid ammonium salt, organic acid amine salt, organic acid amide, organic acid hydrazide, organic acid metal complex, and organic acid metal salt.

4. The CVD film forming method of claim 1, wherein only the reducing organic compound gas is initially supplied into the processing chamber and, then, the metal compound gas and the reducing organic compound gas are supplied into the processing chamber.

5. The CVD film forming method of claim 1, wherein a material of the metal compound gas and a material of the reducing organic compound gas are stored in a mixed state in a single container, and the metal compound gas and the reducing organic compound gas are supplied into the processing chamber from the container.

6. A CVD film forming apparatus comprising:
a processing chamber for accommodating a substrate to be processed;
a mounting table for mounting the substrate thereon in the processing chamber;
a gas supply unit for supplying a metal compound gas and a reducing organic compound gas into the processing chamber;
a gas exhaust unit for evacuating the processing chamber; and
a heating unit for heating the substrate on the mounting table,
wherein the metal compound gas and the reducing organic compound gas are supplied into the processing chamber to form a metal film on a surface of the substrate on the mounting table by a reaction of the gases.

7. The CVD film forming apparatus of claim 6, wherein the gas supply unit includes separate containers for storing a material of the metal compound gas and a material of the reducing organic compound gas, respectively.

8. The CVD film forming apparatus of claim 6, wherein the gas supply unit includes a container for storing a material of the metal compound gas and a material of the reducing organic compound gas in a mixed state, and the metal compound gas and the reducing organic compound gas are supplied into the processing chamber from the container.

9. A CVD film forming apparatus comprising:
at least two film forming units, each unit including a processing chamber for accommodating a substrate to be processed, the processing chamber being maintained in a vacuum state, a mounting table for mounting the substrate thereon in the processing chamber, a gas supply unit for supplying a metal compound gas and a reducing organic compound gas into the processing chamber, a gas exhaust unit for evacuating the processing chamber, and a heating unit for heating the substrate on the mounting table; and
a substrate transfer unit for transferring the substrate between the film forming units without breaking the vacuum state,
wherein a first metal film is formed on a surface of the substrate by a reaction of the metal compound gas and the reducing organic compound gas in any one of the film forming units and, after the substrate is transferred to another one of the film forming units by using the substrate transfer unit, a second metal film is formed on the first metal film continuously by a reaction of the metal compound gas and the reducing organic compound gas without breaking the vacuum state.

10. A storage medium which is operated on a computer and stores a program for controlling a CVD film forming apparatus, wherein the program controls the CVD film forming apparatus to perform a CVD film forming method including:
placing a substrate to be processed in a processing chamber; and
forming a metal film on a surface of the substrate by continuously supplying a metal compound gas and a reducing organic compound gas into the processing chamber.
